(19) United States
(12) Patent Application Publication
(10) Pub. No.: US 2010/0135609 A1
(43) Pub. Date: Jun. 3, 2010

(54) APPARATUS COMPRISING A CYLINDRICAL SUBSTRATE AND AN INTEGRATED OPTICAL CIRCUIT

(76) Inventors: Peter George Robin Smith, Hampshire (GB); Gregory Daniel Emmerson, Hampshire (GB); Samuel Paul Watts, Hampshire (GB); Richard Bird Williams, Hampshire (GB); Alexander Fu, Hertfordshire (GB)

Correspondence Address: Iandioroio Teska &Coleman, 260 Bear Hill Road, Waltham, MA, 02451, US

(21) Appl. No.: 12/451,366

(22) PCT Filed: May 7, 2008
(86) PCT No.: PCT/GB2008/001573

§ 371 Date: Nov. 9, 2009

(30) Foreign Application Priority Data
May 10, 2007 (GB) 0709023.6

(51) Int. Cl. G02B 6/12; B29D 11/00; G03F 7/20

(52) U.S. Cl. 385/14; 264/1.27; 430/321

(57) ABSTRACT

Apparatus (2) comprising a cylindrical substrate (4), and an integrated optical circuit which is provided on the cylindrical substrate and which comprises at least one optical waveguide (6). A process for producing the apparatus (2) is also disclosed.

This invention relates to integrated optical circuits and, more especially, this invention relates to apparatus comprising a substrate and an integrated optical circuit on the substrate. This invention also relates to a process for producing the apparatus.

Optical devices such for example as amplifiers, wavelength multiplexers, and wavelength de-multiplexers process signals carried in optical fibres. Such optical devices have traditionally been constructed from optical fibre. As telecommunications systems move to increase the capacity of optical fibre links, each optical fibre will be carrying many channels, each using a particular wavelength of light. It is widely believed that as this number of channels increases, it will become necessary to use integrated optical circuits to process these channels. Known integrated optical circuits are constructed on flat substrates. Complex integrated optical circuits such for example as amplifiers, often require large optical path lengths. This requires a large substrate, thereby increasing the cost of the circuit. In the case of some optical amplifiers, an ideal optical waveguide length is greater than ten centimetres and up to several metres. This is impractical in integrated optical circuits, without forming the optical waveguide into a spiral on the flat substrate. Due to limitations on the minimum optical waveguide bend radius, a circular optical waveguide will occupy a large area on the flat substrate.

It is an aim of the present invention to reduce the above mentioned problem.

Accordingly, in one non-limiting embodiment of the present invention there is provided apparatus comprising a cylindrical substrate, and an integrated optical circuit which is provided on the cylindrical substrate and which comprises at least one optical waveguide.

The present invention enables a short length of a cylindrical substrate to accommodate one or more waveguides many metres long. This cannot be achieved on a flat substrate without large losses due to the small bend radii that would be required. The cylindrical substrate may be one which is completely cylindrical, or it may be one which is substantially cylindrical, for example having ellipticity in the cylinder caused deliberately or occurring during manufacture.

The use of a cylindrical substrate instead of a conventional flat substrate enables the use of long optical waveguides in a small substrate area. The apparatus of the present invention may thus be produced in compact form. The apparatus may be produced in modular optical component form, allowing production cost savings since standard components can be produced and then assembled into circuits. The circuits may be reconfigurable and repairable.

The apparatus may be one in which the integrated optical circuit is on the inside and/or the outside of the cylindrical substrate.

Preferably, the optical waveguide is formed in a spiral around a longitudinal axis of the cylindrical substrate. The spiral may be formed with any suitable and appropriate pitch. The optical waveguide may be formed on the cylindrical substrate in configurations other than a spiral if desired.

The integrated optical circuit may include at least one device used in conventional flat integrated optical circuits.

The device may be a passive device. Typical passive devices are a coupler, a splitter, a diffraction grating, a multiplexer, or a switch. The diffraction grating may be used for dispersion compensation.

Alternatively, the device may be an active device. Typically, the active device may be a laser or an amplifier.

The apparatus of the present invention may include electrodes on the optical waveguide, thereby allowing the material of the optical waveguide to be subjected to an electric field.

The material of the optical waveguide may be an electro-optic material, whereby the electric field is able to induce a refractive index change in the optical waveguide. The electro-optic material may be an electro-optic polymer material or poled silica. The electro-optic polymer material may be one whose refractive index may be controlled by an electric field.

When the material of the optical waveguide is an electro-optic material, then the optical waveguide may form part of an interference device, whereby a change in the refractive index is able to cause a change in intensity of the output of the interference device. The interference device may be, for example, a Mach-Zender interferometer, or a directional coupler.

The electrode structure may be configured to allow the electrodes to skip from one revolution of the optical waveguide to a next revolution of the optical waveguide, thereby providing a significant path length difference between electrical and optical waves whereby the electrical and optical waves are able to be kept in phase.

Alternatively, the apparatus may be one in which a difference in pitch between electrical and optical waveguides is such that the electrical waveguide length is less than the optical waveguide length so that the time taken for an electrical wave to propagate through the apparatus is equal to the time taken for an optical wave to propagate through the apparatus and thus the electrical and optical waves are able to be kept in phase.

The apparatus of the present invention may include at least one input device, and at least one output device.

The input device and/or the output device may be connected to one or more optical fibres.

Alternatively the input device and/or the output device may be connected to one or more flat optical circuits.

The input device and/or the output device may be connected by close coupling the optical fibre or the flat optical circuit to a step in the cylindrical substrate, thereby to allow multiple cylindrical circuits to be stacked on top of each other.

Alternatively, the input device and/or the output device may be connected to the optical fibre or the flat optical circuit by a bend in the optical waveguide so that the optical waveguide travels parallel to the longitudinal axis of the cylinder. The input device may be located at a point where the optical waveguide meets an end of the cylindrical substrate.

The apparatus of the present invention may be in the form of a multiple channel grating dispersion compensator, a multiple channel amplifier, or a multiple channel transmitter.

The apparatus of the present invention may be one in which the integrated optical circuit is a laser-written integrated optical circuit.

The present invention also provides a telecommunications system when including the apparatus of the invention.

The present invention further provides a process for producing the apparatus of the invention, which process comprises providing the cylindrical substrate; providing a slab waveguide comprising a core layer for forming a core of the optical waveguide, and a cladding layer at least above the core layer; and providing a channel optical waveguide in the slab waveguide.

Preferably, the cladding layer is also provided below the core layer. However, if desired, the cylindrical substrate may form a cladding layer under the core layer.

The process may be one in which the channel optical waveguide is provided by causing the refractive index of the core layer to be higher in the channel than elsewhere in the apparatus.

The refractive index of the core layer may be caused to be higher in the channel than elsewhere in the apparatus by starting with a photosensitive core layer with a refractive index equal to or greater than that of the cladding, and then using a laser beam to increase the refractive index of the region in the photosensitive core layer that will form the core of the optical waveguide. The laser beam is preferably an ultraviolet laser beam. Other laser beams may however be employed.

Alternatively, the refractive index of the core layer may be caused to be higher in the channel than elsewhere in the apparatus by removing material of the core layer everywhere except where the channel is required, and then depositing more core layer material and of a slightly lower refractive index in order to replace the removed material of the core layer.

The slab waveguide may be formed on the outside of the cylindrical substrate using flame hydrolysis deposition.

Alternatively, the slab waveguide may be formed on the inside of the cylindrical substrate using a modified chemical vapour deposition process.

The slab waveguide for the above described processes may be, for example, a silicate slab waveguide.

Alternatively, the slab waveguide may be a polymer slab waveguide. With a polymer slab waveguide, the channel optical waveguide may be produced by ultraviolet writing.

In an alternative embodiment of the process of the invention, the channel optical waveguide may be produced by depositing a cladding layer and a core layer, depositing a layer of photo-resist, exposing the pattern of a desired circuit in the photo-resist, developing the photo-resist to leave the photo-resist only where the channel optical waveguide is required, etching away the region of the core that is not covered by photo-resist, removing the photo-resist, and depositing a cladding layer over the circuit. The pattern of the desired circuit in the photo-resist may be exposed using ultra violet writing with a low power laser. Conventional photo-lithography cannot be used since the substrate is not flat.

Embodiments of the invention will now be described solely by way of example and with reference to the accompanying drawings in which:

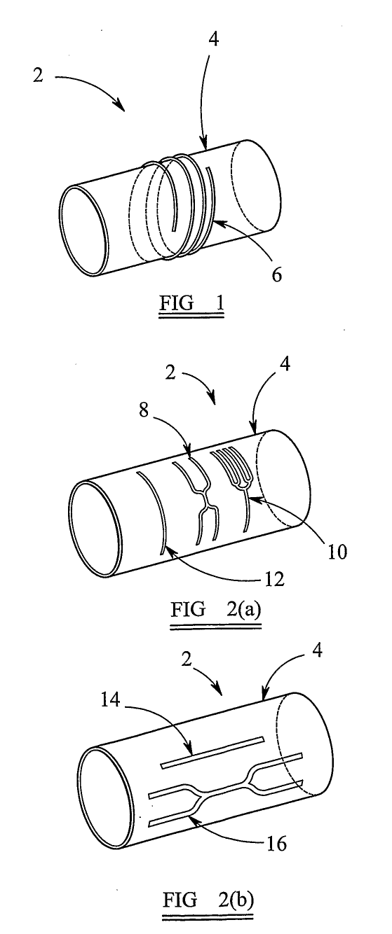

FIG. 1 shows apparatus of the invention in which a long channel optical waveguide spirals around a cylindrical substrate;

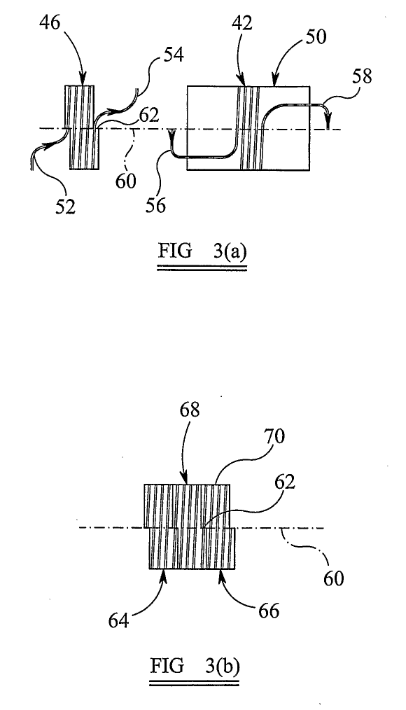

FIGS. 2(a) and (b) show a cylindrical substrate provided with various devices used in conventional flat integrated optical circuits;

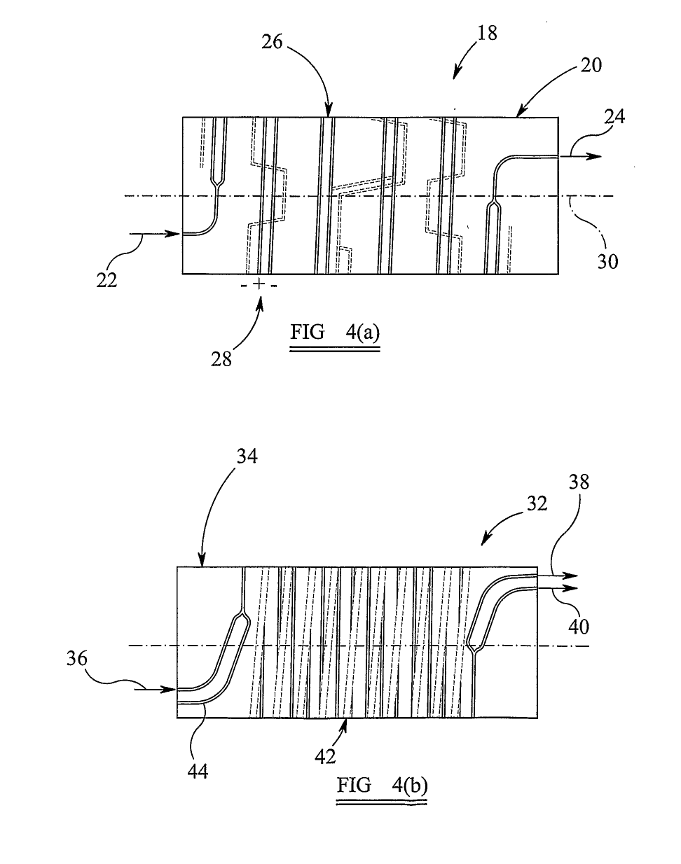

FIG. 3(a) illustrates methods of optical connection to optical waveguides on a cylindrical substrate;

FIG. 3(b) illustrates how three separate optical circuits may be coupled together in a modular fashion;

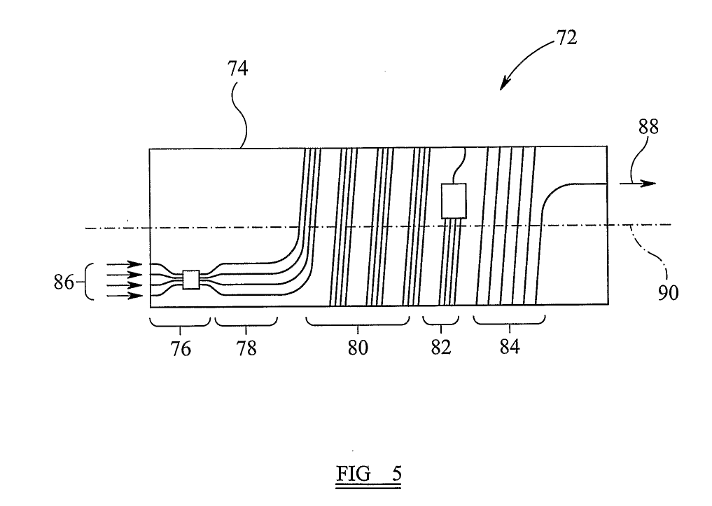

FIGS. 4(a) and (b) illustrate optical modulators formed from apparatus of the present invention, the optical modulators being in poled glass produced on a cylindrical substrate;

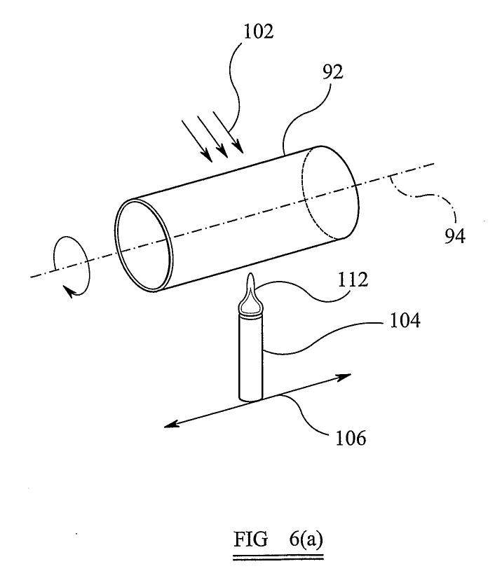

FIG. 5 shows second apparatus of the present invention;

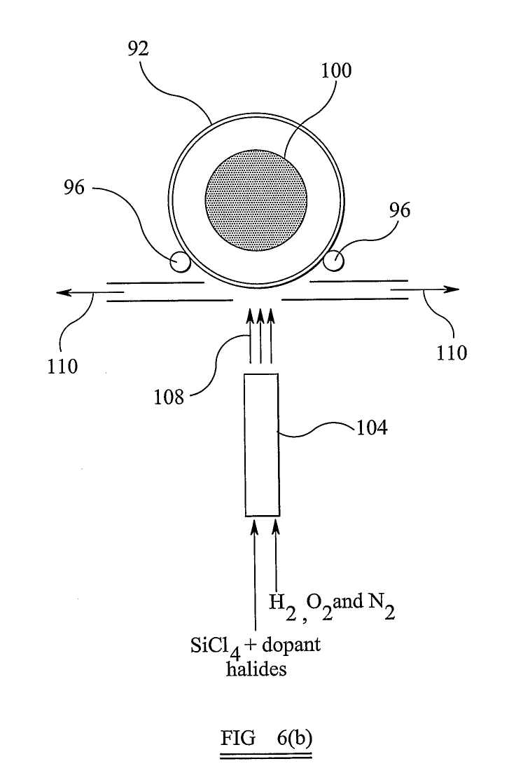

FIG. 6(a) illustrates how apparatus of the present invention may be produced by depositing an integrated optical circuit on the outside of a cylindrical substrate using flame hydrolysis deposition;

FIG. 6(b) illustrates in more detail than FIG. 6(a) how apparatus of the present invention may be produced by depositing an integrated optical circuit on the outside of a cylindrical substrate using flame hydrolysis deposition;

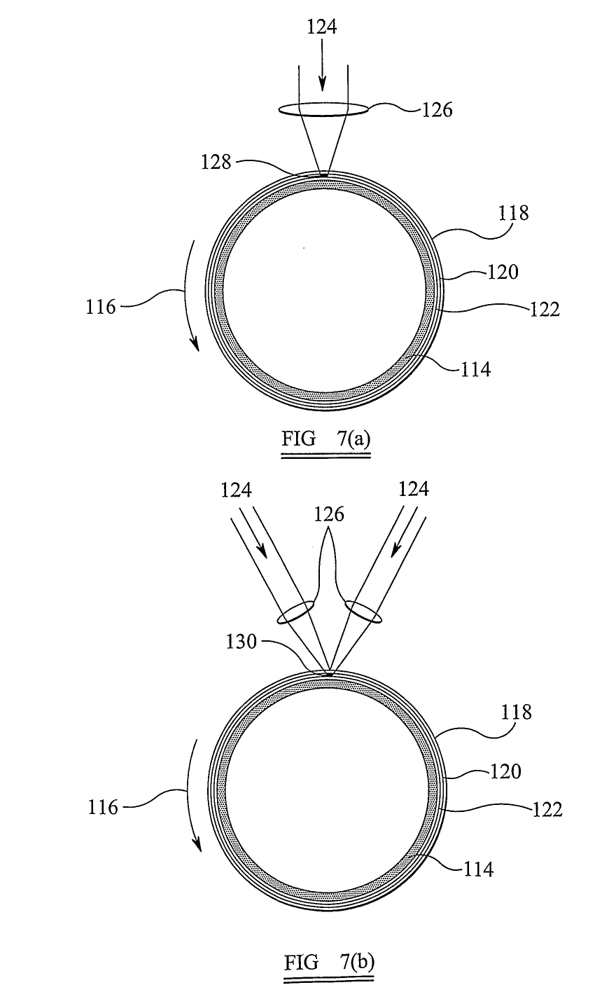

FIGS. 7(a) and (b) illustrate ultraviolet writing into slab waveguides on a cylindrical substrate; and

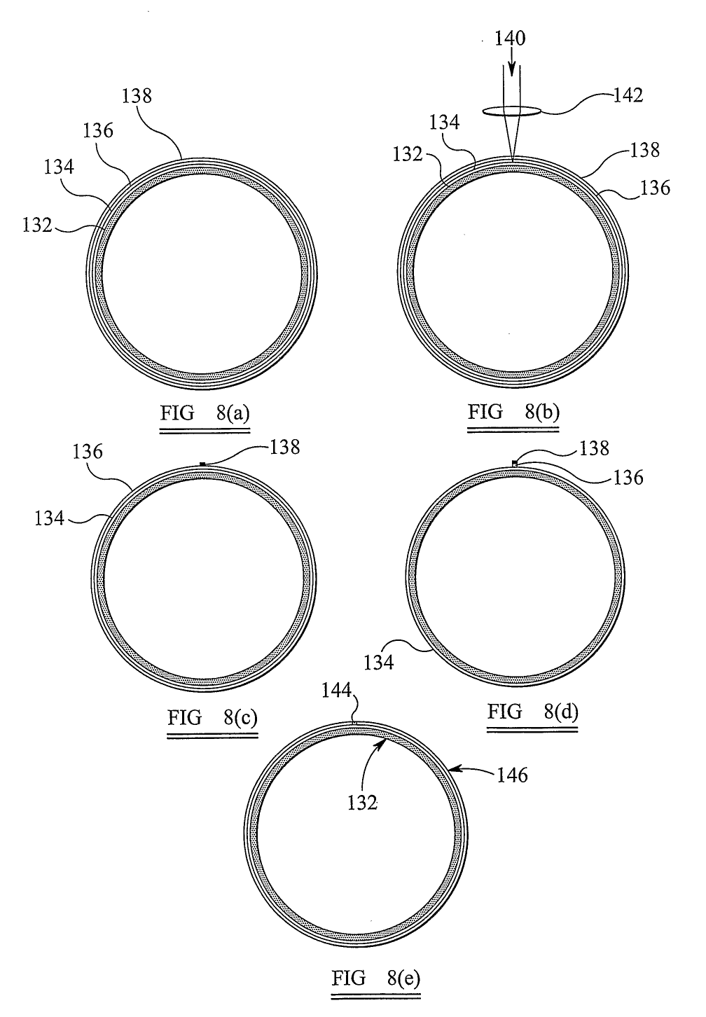

FIGS. 8(a)-(e) illustrate an etching process for producing channel waveguides.

Referring now to FIG. 1, there is shown apparatus 2 comprising a cylindrical substrate 4 and an integrated optical circuit which is provided on the cylindrical substrate 4 and which comprises an optical waveguide 6. The waveguide 6 is an optical channel waveguide 6 which is of a long length and which spirals as shown around the cylindrical substrate 4. The optical waveguide 6 is provided on the outside of the cylindrical substrate 4. The optical waveguide 6 is formed in a spiral around a longitudinal axis of the cylindrical substrate 4. In this manner, a short length of cylindrical substrate 4 as shown in FIG. 1 is able to accommodate the optical waveguide 6 which may be many metres long. Thus the apparatus 2 can be compact and without losses in propagation through the optical waveguide 6 as would occur if the optical waveguide 6 were provided on a flat substrate which would then require small bend radii for the optical waveguide in order to accommodate it on the flat substrate. FIG. 1 is given for illustrative purposes only and it is to be appreciated that the integrated optical circuit may comprise more than one of the optical waveguides 6.

The integrated optical circuit containing the optical waveguide 6 may include at least one device used in conventional flat integrated optical circuits. Thus, referring to FIG. 2(a), it will be seen that the apparatus 2 may include passive devices in the form of a coupler 8, a splitter 10, and a waveguide with a diffraction grating 12.

In addition to passive devices, the optical waveguides may be doped with a rare earth element, for example erbium or ytterbium, in order to produce regions with gain. This allows the apparatus 2 to include active devices. In FIG. 2(b), the apparatus 2 is shown such that the cylindrical substrate 4 is provided with an active devices in the form of a laser 14. The active device could alternatively or in addition be an amplifier (not shown). The cylindrical substrate 4 shown in FIG. 2(b) is also shown provided with a passive device in the form a coupler 16.

Because the substrate 4 is a cylindrical substrate 4, active device waveguides may be many metres long, allowing the construction of effective amplifiers in an integrated optical circuit. Also, long diffraction gratings may be produced, allowing dispersion compensation devices to be integrated. For simplicity of illustration in FIGS. 2(a) and (b), the optical waveguide 6 of FIG. 1 has not been shown. The apparatus 2 may generally contain any waveguide structure that may be created on a flat substrate. The waveguide structure may be parallel to the longitudinal axis of the cylindrical substrate 4, or at any other angle.

The apparatus of the present invention may include electrodes on the optical waveguide, thereby allowing the material of the optical waveguide to be subjected to an electric field.

Preferably, the material of the optical waveguide is an electro-optic material, whereby the electric field is able to induce a refractive index change in the optical waveguide. The electro-optic material may be an electro-optic polymer material or poled silica. The electro-optic polymer material may be, for example, polyurethane with side chains known as disperse red 19 side chains. With the use of the electro-optic material, an electric field is able to induce a refractive index change in the optical waveguide. Thus the optical waveguide may form part of an interference device, whereby a change in the refractive index is able to cause a change in intensity of the output of the interference device. The interference device may be, for example, a Mach-Zender interferometer, or a directional coupler.

In the above manner, a waveguide modulator may be made. If a waveguide modulator were to be made with a flat substrate using poled silica as the electro-optic material, because the electro-optic co-efficient is so small, many meters of optical waveguide path length would be required. The use by the present invention of the cylindrical substrate enables the cylindrical substrate to support the long interaction optical waveguide lengths required.

A further advantage of the use of a cylindrical substrate is that it provides new methods of matching the velocity of electrical and optical signals so that the electrical and optical signals may efficiently interact over several metres. In conventional known modulators produced in a lithium niobate flat substrate, there are two commonly used methods of keeping the electrical and optical signals in phase. The first method is to design the travelling wave electrode structure so that the refractive index that the modulating microwave signal experiences is the same as the refractive index that the optical signal experiences, thereby ensuring that the two waves propagate at the same speed. A disadvantage with this method is, that these restrictions on the electrode design mean that it is not possible to match the impedance of the electrode structure to that of the driving circuit, resulting in reflections at the input to the electrode structure. The second known method is to reverse the directions of the electric field whenever the electrical and the optical signals get 180° out of phase. As shown in FIG. 4, this is done by shifting the electrode structure sideways so that the ground electrode is above the waveguide instead of the signal electrode.

FIG. 4 also shows apparatus in accordance with the present invention, and, in particular, shows how the electrical and optical signals are able to be kept in phase using the cylindrical geometry afforded by the cylindrical substrate. FIG. 4(a) shows apparatus 18 comprising a cylindrical substrate 20. The cylindrical substrate 20 is provided with an input 22, an output 24, an optical waveguide Mach-Zender interferometer modulator 26 and travelling wave electrodes 28. The cylindrical substrate 20 is shown with a longitudinal axis 30. The apparatus 18 illustrates that it is possible for the electrode structure to skip from one revolution of the waveguide to the next, enabling significant path length difference between the electrical and optical waveguides so that the electrode structure may be designed to keep the two signals in phase. More specifically, as shown in FIG. 4(b), the Mach-Zender interferometer modulator which is provided on the cylindrical substrate 20 uses the electrical reversal technique to help maintain phase matching between the electrical and optical waves. More specifically, the electrode structure is arranged as shown in FIG. 4(a) so that the direction of the modulating electric field is reversed periodically as the electrical and optical waves become out of phase. In this manner, constructive modulation of the light is maintained over the large length necessary to achieve modulation, for example in poled glass. In addition to the periodic reversal of the electrodes, the electrodes are able to skip from one revolution of the optical waveguide to the next as mentioned above and as shown. Thus the electrical and optical waves are able to be kept in phase.

Referring to FIG. 4(b), there is shown apparatus 32 comprising a cylindrical substrate 34 having an input 36, an output 38, an inverted output 40 and an electrical waveguide structure 42. The electrical waveguide structure 42 is spiraled with a greater optical pitch than a long optical waveguide structure in the form of a long optical waveguide coupler 44. The electrical waveguide structure 42 forms a modulator based on a directional coupler. The electrode structure is spiraled around the cylindrical substrate 34 with a greater pitch than the optical waveguide coupler 44. The difference in pitch between the electrical and optical waveguides is carefully chosen so that the electrical waveguide length is less than the optical waveguide length. This enables the time taken for the electrical wave to propagate through the apparatus 32 to be exactly equal to the time taken by the optical wave. Thus the electrical and optical waves remain in phase through their propagation through the apparatus 32. Advantageously, the design of the modulator in the form of the electrical waveguide structure 42 does not suffer from a restricted range of modulation frequencies, as occurs with designs using the electrode reversal method.

Referring now to FIGS. 3(a) and (b), the input and output of waveguides from a cylindrical circuit may be connected to optical firbre or conventional flat optical circuits. One method of such connection is shown in FIG. 3(a) which shows a method of optical connection of a waveguide 46 on a cylindrical substrate (not shown) and a waveguide 48 on a cylindrical substrate 50. The waveguide 46 has an optical fibre input 52 and an optical fibre output 54. The waveguide 48 has an optical fibre input 56 and an optical fibre output 58. The cylindrical substrate for the waveguide 46 and the cylindrical substrate 50 have a longitudinal axis 60. The connection is effected by close coupling the fibre or optical circuit to a small step 62 cut in the cylindrical substrate. This method of connection allows multiple cylindrical circuits to be stacked on top of each other as shown in FIG. 3(b). More specifically, FIG. 3(b) shows how three separate optical circuits may be coupled together in a modular fashion. In FIG. 3(b), there are shown a previous optical waveguide circuit 64, a subsequent optical waveguide circuit 66, and an optical waveguide 68 on a cylindrical substrate 70. Also shown in FIG. 3(b) is the step 62 and the longitudinal cylinder axis 60. The light in the optical waveguides automatically travels from one circuit to the next, due to the precise alignment given by supporting the individual cylindrical substrates on a common mandrel (not shown). The mandrel may be internal or external to the cylindrical optical waveguide circuits. This allows the creation of modular optical circuits. An alternative method to connecting optical fibres or other optical circuits to the cylindrical circuit, is to produce a bend in the optical waveguide so that that waveguide travels parallel to the axis of the cylindrical substrate. The point where the optical waveguide meets the end on the cylinder may be used to couple light to the waveguide as shown in FIG. 3(a).

The present invention enables the production of many key devices for telecommunications systems. By way of example, reference is made to FIG. 5 which shows apparatus 72 comprising a cylindrical substrate 74 containing a star coupler 76, DFB or DBR lasers 78, a modulator 80, a coupler 82 and an amplifier 84. The apparatus 72 is shown with pump diode 86, lasers, a WDM modulated output 88 and a longitudinal axis 90.

The apparatus 72 shown in FIG. 5 takes pump power input from pump diode lasers 86. The light from these pump diode lasers 86 is combined as shown and then split up again, in order to provide redundancy of the pump lasers 86 which are the most likely components to fail. The pumped light is then directed to the DFB or BDR lasers 78, written using diffraction gratings along the axis 90 of the cylindrical substrate 74. Producing these lasers 78 along the axis of the cylindrical substrate 74 makes writing the diffraction grating more straight forward. However, if desired, the laser 78 may be produced around the cylindrical substrate 74. The output from the lasers 78 is then modulated by the modulator 80. The modulated signals are then multiplexed into a single waveguide which is then amplified by the amplifier 84, ready for launch into a fibre via the WDM modulated output 88. The laser and amplifier sections 78, 84 respectively of the apparatus 72 maybe doped with erbium in order to prevent gain at 1.5 μm.

The apparatus of the present invention is very advantageous commercially. The commercial market for integrated optical circuits is worth many millions of pounds per year, and it is driven by the need for WDM and DWDM systems to add more capacity to optical fibre networks. The processing of signals in the WDM systems with a large number of channels is best performed with integrated optical circuits rather than the currently used fibre devices. Using the currently used fibre devices requires at least one fibre per WDM channel. Since there will be hundreds of channels per transmission fibre, this leads to an unmanageable number of fibres within a signal processing system. With an integrated optical system afforded by the present apparatus, these known hundreds of channels are able to be processed on a single integrated optical circuit, which is more compact, and more economical to mass produce than the equivalent fibre system.

With integrated optical devices, it has hitherto been difficult to produce efficient optical amplifiers and modulators on a small substrate. This is not a problem with the present invention and consequently the present invention is of considerable benefit to the majority of WDM systems.

The apparatus of the present invention may be fabricated in the form of passive and active optical waveguides on cylindrical substrates. A first process for producing integrated optical circuits on a cylindrical substrate is as follows.

Core and cladding layers are produced on a cylindrical substrate. The core layer is the layer that forms the core of the optical channel waveguide. The cladding layers are the layers above and below the core. In some cases, the cylindrical substrate may form the under cladding layer. By the process so far described, a slab waveguide is formed. It is then necessary to produce channel waveguides in the slab waveguide. This requires the refractive index of the core region to be higher in the channel than elsewhere. This may be achieved in two ways. The first way is to start with a photosensitive core layer with a refractive index equal to or greater than that of the cladding, and to use an ultraviolet beam to increase the refractive index of the region in this layer that will form the waveguide core. The second way is to remove the material of the core layer everywhere except where the channel is required, and then to deposit more glass, of a slightly lower refractive index, in order to replace the removed material in the core layer.

Referring now to FIG. 6, there is shown a modified version of flame hydrolysis deposition which is a suitable method for producing silicate slab waveguides on a cylindrical substrate. FIG. 6(a) illustrates the concept of flame hydrolysis deposition on the outside of a cylindrical substrate. FIG. 6(b) shows schematically the flame hydrolysis deposition on the outside of the cylindrical substrate. In FIGS. 6(a) and (b), there is shown a cylindrical substrate 92 having a longitudinal axis 94. The cylindrical substrate 92 is rotated by powered wheels 96. The rotation of the cylindrical substrate 94 is in a clockwise direction as indicated by arrows 98. A heater 100 is employed to control the temperature of the cylindrical substrate 92. The heater 100 provides heat shown schematically as heater 102 in FIG. 6(a).

A burner 104 traverses backwards and forwards as shown by arrow 106. The burner 104 provides a stream of oxide particles 108. Waste gas is extracted via waste gas extracts 110. The burner 104 receives SiCl₄ plus dopant halides. The burner 104 also received hydrogen, oxygen and nitrogen as shown in FIG. 6(b).

In operation of the apparatus shown in FIGS. 6(a) and 6(b) vapours of halide such as SiCl₄, GeCl₄, POCl₃, PCl_{S}, BCl₃ and BBr₃ are fed into a hydrogen-oxygen flame where the halides are oxides to produce particles of silicate glass doped with the other species. The cylindrical substrate 92 is positioned in the flame 112 as shown in FIG. 6(a), and the oxides are deposited as amorphous particles on the surface of the cylindrical substrate 92. It is necessary to use the heater 100 in order to control the temperature of the cylindrical substrate 92 so that the oxide particles are deposited in a glassy phase and not a crystal phase. The burner 104 is designed with multiple rings. This design enables the gases to be separated from each other by an inert gas so that the reactions take place a small distance above the burner 104. This prevents the glass particles from being deposited on the burner nozzle. The cylindrical substrate 92 is rotated, and the burner 104 moves backwards and forwards along the axis of the cylindrical substrate 94 as indicated by the arrow 106. In this manner, a uniform layer of glass particles is formed on the outside of the cylindrical substrate 92. The cylindrical substrate 92 and the layer of the glass particles are then heated in a furnace to temperatures between 1200-1400° C. so that the layer of particles is sintered to form a solid glass layer. The exact sintering temperature and the time of sintering depend on the composition and the size of the particles. An alternative to using a furnace for sintering is to use the hydrogen-oxygen flame to heat the sample after or during deposition. Layers of different refractive index are deposited by repeating the above process with different halide dopent concentrations in the flame. In this manner, slab waveguides are able to be produced on the outside of the cylindrical substrate 92.

If desired, slab waveguides may be produced on the inside of the cylindrical substrate using a modified chemical vapour deposition process. This modified chemical vapour deposition process involves rotating the cylindrical substrate 92 on a lathe and passing the vapours of halides such as SiCl₄, GeCl₄, POCl₃, PCl_{S}, BCl₃ and BBr₃ together with oxygen through the cylinder. A heat source, for example a hydrogen-oxygen flame, is then traversed along the axis of the cylinder. In the region that is heated by the flame, the halides react with the oxygen producing oxide particles that deposit on the inside of the cylinder. The particles can then be consolidated into a glass layer by heating with the flame. Repeating this process with different amounts of dopants yields layers with different refractive indices and photosensity.

As an alternative to using silicate slab waveguides, polymer slab waveguides may be produced on the inside of the cylindrical substrate 92 by rotational casting. This rotational casting involves rotating the cylindrical substrate 92 and introducing a liquid polymer into the cylindrical substrate 92. Due to the rotation of the cylindrical substrate 92, the liquid polymer is uniformly distributed on the interior surface of the cylindrical substrate 92. The polymer then solidifies, either by evaporation of solvent or by a chemical reaction causing crosslinking. This process is repeated in order to build up thicker layers, or to add layers of a different refractive index. Polymer layers may be produced on the outside of the cylinder by spraying in a manner similar to that commonly used to apply photo-resist to non-flat samples.

Channel waveguides may be defined in the produced slab waveguides using ultraviolet writing. The ultraviolet writing relies on the material of the core region of the slab waveguide being photosensitive, i.e. showing a change in refractive index after exposure to intense ultraviolet light. The ultraviolet light source is preferably a frequency doubled argon ion laser working at 244 nm, or an excimer laser working at 248 nm or 193 nm. If the optical waveguide is a silicate, then doping with germanium, boron or tin oxides may be employed to yield photo sensitive glasses. These materials may be loaded with hydrogen or deuterium prior to the ultraviolet writing in order to increase the photosensitivity. Only the core material is photosensitive so that when the ultraviolet laser beam is focused onto the sample, the refractive index of the region of the core material that is exposed increases, thus yielding a channel waveguide.

Referring now to FIGS. 7(a) and (b) there is shown the above mentioned ultraviolet writing into slab waveguides on a cylindrical substrate.

More specifically, FIGS. 7(a) and (b) show a cylindrical substrate 114 which is rotated anti-clockwise as shown by arrow 116. The cylindrical substrate 114 is provided with outer cladding 118, a core 120 and under cladding 122. FIG. 7(a) shows an ultraviolet laser 124 with a lens 126 forming an optical channel waveguide 128. FIG. 6(b) shows two of the lasers 124 forming a grating pattern 130. Thus in FIG. 7(a), the laser 124 is used to write the optical channel waveguide 128. In FIG. 7(b), the lasers 124 are used to write the grating pattern 130.

In FIGS. 7(a) and (b), the cylindrical substrate 114 is mounted on a turntable (not shown). The laser beam is focused onto the slab waveguide core. The laser beam is then translated along the axis of the cylindrical substrate 114 as the cylindrical substrate 114 rotates, thus effecting the desired ultraviolet laser writing. The optical channel waveguide 128 is in the form of spiral waveguide. The angular position of the cylindrical substrate 114 is monitored by a computer (not shown) which controls the position of the writing spot. The apparatus employed may be programmed to produce different channel waveguides such for example as coupler, Mach-Zender interferometers, etc. Diffraction gratings as shown by the grating pattern 130 in FIG. 7(b) may be written into the waveguides. This may be effected either by positioning a phase mask immediately above the writing region, or by constructing the writing spot from two beams as shown in FIG. 7(b) with the two beams interfacing to produce the grating pattern. Gratings far longer than the writing spot may be produced by modulating the laser intensity so that the laser beam is only present when the cylindrical substrate has rotated by an integer number of grating periods. In order to produce high quality waveguide structures and gratings, the position of the writing spot or the grating pattern is controlled very accurately. This extreme accuracy is required because any areas in the grating which are as small as even a few percent of the grating period, which is typically 0.5 μm, will have a significant affect on the performance of the grating. Also, any uncertainty of the order of 0.1 μm in the position of the waveguide will result in scattering losses at a junction. These high tolerances will require active feedback to control the position of the writing spot, both in the axial and radial directions. Also, feedback will be required to compensate for any eccentricity in the cylinder.

FIG. 8 illustrates an alternative method of producing optical channel waveguides. More specifically, FIGS. 8(a)˜(e) show a cylindrical substrate 132 having cladding 134, a core 136 and photo-resist 138. FIG. 8(b) shows the use of a laser beam 140 with a lens 142. FIG. 8(c) shows exposed photo-resist 138 after developing. FIG. 8(d) shows the photo-resist 138 and the channel core 136 after etching. FIG. 8(e) shows the cylindrical substrate 132 having a channel waveguide 144 and a final layer of cladding 146 deposited.

The production of the channel waveguides shown in FIG. 8 is undertaken as follows.

The cladding layer 132 and the core 136 are deposited on the cylindrical substrate 132. The layer of photo-resist 138 is then deposited. This may be done by rotational casting on the inside of the cylindrical substrate 132. Alternatively, it may be done by dip coating or spraying on the outside of the cylindrical substrate 132. The pattern of the desired circuit is then exposed in the photo-resist 138 by ultraviolet writing with a low power laser providing the low power laser beam 140. Conventional photo-lithography cannot be used since the substrate 132 is cylindrical and not flat. The photo-resist 138 is then developed, leaving exposed photo-resist 138 only where the channel is required, see FIG. 8(c). The region of the core 136 that is not covered by photo-resist is then etched away as shown by FIG. 8(d). The photo-resist 138 is then removed. The final layer of cladding 146 is then deposited over the top of the formed integrated optical circuit.

In order to make an optical modulator in accordance with the present invention, the material of the optical waveguide must be electro-optic. The electro-optic material may be the above mentioned polyurethane with the side chains known as dispense red 19 side chains, or it may be silicate glasses that have been poled. Poling of the optical waveguide material may be achieved by depositing a thin electrode on the outer surface of the waveguide structure, and a second electrode on the other side of the substrate. When a high voltage is applied between the two electrodes, a large electric field is generated across the waveguide material. The entire device is heated whilst this electrical field is applied in order to cause the material to pole. The poling is permanent if the device is cooled down to room temperature before the electric field is removed. The electrodes may be metal films deposited by any suitable and appropriate known techniques, including evaporation and sputtering. If desired, the electrode may be etched away after the poling has been completed.

In accordance with the present invention, a modulator may be made by producing a Mach-Zender Interferometer in which one or both light paths are in the electro-optic material. The intensity at the output of the Mach-Zender Interferometer depends upon the relative phase of the light from each arm of the Mach-Zender Interferometer. This phase difference can be modulated by changing the relative optical path length along each arm of the Mach-Zender Interferometer. This modulation may be achieved by modulating the voltage across one of the interferometer arms, thereby changing the refractive index and optical path length of that arm of the interferometer. Alternatively, voltages of opposing signs may be applied across both of the interferometer arms, thereby reducing the optical path length in one arm and increasing the optical path length in the other arm. Instead of using a Mach-Zender interferometer, a directional coupler may be used. In the case of a directional coupler, the signal introduced into one input and the ratio of the intensity of light at the two outputs may be determined by the optical path length in the coupling region. If this coupling region is electro-optic, then an applied voltage will modulate the output from one arm of the coupler.

After producing the waveguide structure, and after effecting any required poling, electrodes may be deposited on the outer surface of the waveguide structure. This may be done by a modified photolithography technique. A metal film may then be deposited as a layer of photo-resist sprayed or rotationally cast onto the metal film. Ultraviolet writing may be used to write the electrode pattern into the photo-resist, which is then developed. The metal is then etched in the regions where there is no photo-resist, thus yielding the desired electrode structure.

There are three major considerations that determine the design of the electrode structure. Firstly, the electrical wave must take the same length of time to travel through the modulator as the optical signal. Secondly, the loss of the electrical waveguide must be sufficiently low to enable the electrical signal to propagate along the device and still produce a refractive index modulation at the end of the device. Thirdly, the impedance the electrical waveguide is preferably 50Ω so that the modulator may be matched to the drive circuit to prevent a large reflection of the electrical wave at the input to the device.

It is to be appreciated that the embodiments of the invention described above with reference to the accompanying drawings have been given by way of example only and that modifications may be effected.

1. Apparatus comprising a cylindrical substrate, and an integrated optical circuit which is provided on the cylindrical substrate and which comprises at least one optical waveguide.

2. Apparatus according to claim 1 in which the integrated optical circuit is on the inside of the cylindrical substrate.

3. Apparatus according to claim 1 in which the integrated optical circuit is on the outside of the cylindrical substrate.

4. Apparatus according to claim 1 in which the integrated optical circuit is on the inside and the outside of the cylindrical substrate.

5. Apparatus according to claim 1 in which the optical waveguide is formed in a spiral along a longitudinal axis of the cylindrical substrate.

6. Apparatus according to claim 1 any one of the preceding claims in which the integrated optical circuit includes at least one device used in conventional flat integrated optical circuits.

7. Apparatus according to claim 6 in which the device is a passive device.

8. Apparatus according to claim 7 in which the passive device is a coupler, a splitter, a diffraction grating, a multiplexer, or a switch.

9. Apparatus according to claim 6 in which the device is an active device.

10. Apparatus according to claim 9 in which the active device is a laser or an amplifier.

11. Apparatus according to claim 1 and including electrodes on the optical waveguide, thereby allowing the material of the optical waveguide to be subjected to an electric field.

12. Apparatus according to claim 11 in which the material of the optical waveguide is an electro-optic material, whereby the electric field is able to induce a refractive index change in the optical waveguide.

13. Apparatus according to claim 12 in which the electro-optic material is an electro-optic polymer material or poled silica.

14. Apparatus according to claim 12 in which the optical waveguide forms part of an interference device, whereby a change in the refractive index is able to cause a change in intensity of the output of the interference device.

15. Apparatus according to claim 14 in which the interference device is a Mach-Zender Interferometer, or a directional coupler.

16. Apparatus according to claim 11 in which the electrode structure is configured to allow the electrodes to skip from one revolution of the optical waveguide to a next revolution of the optical waveguide, thereby providing a significant path length difference between electrical and optical waves whereby the electrical and optical waves are able to be kept in phase.

17. Apparatus according to claim 11 in which a difference in pitch between electrical and optical waveguides is such that the electrical waveguide length is less than the optical waveguide length so that the time taken for an electrical wave to propagate through the apparatus is equal to the time taken for an optical wave to propagate through the apparatus and thus the electrical and optical waves are able to be kept in phase.

18. Apparatus according to claim 1 and including at least one input device, and at least one output device.

19. Apparatus according to claim 18 in which the input device and/or the output device are connected to one or more optical fibres.

20. Apparatus according to claim 18 in which the input device and/or the output device are connected to one or more flat optical circuits.

21. Apparatus according to claim 19 in which the input device and/or the output device are connected by close coupling the optical fibre or the flat optical circuit to a step in the cylindrical substrate, thereby to allow multiple cylindrical circuits to be stacked on top of each other.

22. Apparatus according to claim 19 in which the input device and/or the output device are connected to the optical fibre or the flat optical circuit by a bend in the optical waveguide so that the optical waveguide travels parallel to the longitudinal axis of the cylinder.

23. Apparatus according to claim 22 in which the input device is located at a point where the optical waveguide meets an end of the cylindrical substrate.

24. Apparatus according to claim 1 in which the apparatus is in the form of a multiple channel grating dispersion compensator, a multiple channel amplifier, or a multiple channel transmitter.

25. Apparatus according to claim 1 in which the integrated optical circuit is a laser-written integrated optical circuit.

26. A telecommunications system when including apparatus according to claim 1.

27. A process for producing apparatus according to claim 1 which process comprises providing the electrical substrate; providing a slab waveguide comprising a core layer for forming a core of the optical waveguide, and a cladding layer at least above the core layer; and providing a channel optical waveguide in the slab waveguide.

28. A process according to claim 27 in which the cladding layer is also provided below the core layer.

29. A process according to claim 27 in which the channel optical waveguide is produced by causing the refractive index of the core layer to be higher in the channel than elsewhere in the apparatus.

30. A process according to claim 29 in which the refractive index of the core layer is caused to be higher in the channel than elsewhere in the apparatus by starting with a photo sensitive core layer with a refractive index equal to or greater than that of the cladding, and then using a laser beam to increase the refractive index of the region in the photo sensitive core layer that will form the core of the optical waveguide.

31. A process according to claim 30 in which the laser beam is an ultraviolet laser beam.

32. A process according to claim 29 in which the refractive index of the core layer is caused to be higher in the channel than elsewhere in the apparatus by removing material of the core layer everywhere except where the channel is required, then depositing more core layer material and of a slightly lower refractive index in order to replace the removed material of the core layer.

33. A process according to claim 27 in which the slab waveguide is formed on the outside of the cylindrical substrate using flame hydrolysis deposition.

34. A process according to claim 27 in which the slab waveguide is formed on the inside of the cylindrical substrate using a modified chemical vapour deposition process.

35. A process according to claim 27 in which the slab waveguide is a silicate slab waveguide.

36. A process according to claim 27 in which the slab waveguide is a polymer slab waveguide.

37. A process according to claim 27 in which the channel optical waveguide is produced by ultraviolet writing.

38. A process according to claim 27 in which the channel optical waveguide is produced by depositing a cladding layer and a core layer, depositing a layer of photo-resist, exposing the pattern of a directional circuit in the photo-resist, developing the photo-resist to leave the photo-resist only where the channel optical waveguide is required, etching away the region of the core that is not covered by photo-resist, removing the photo-resist, and depositing a cladding layer over the circuit.

39. A process according to claim 38 in which the patter of the desired circuit in the photo-resist is exposed using ultraviolet writing with a low power laser.
